(19) United States
(12) Patent Application Publication
(10) Pub. No.: US 2024/0124758 A1
(43) Pub. Date: Apr. 18, 2024

(54) HEAT-CONDUCTIVE SHEET, HEAT-CONDUCTIVE SHEET PRODUCTION METHOD, AND ELECTRONIC EQUIPMENT

(71) Applicant: DEXERIALS CORPORATION, Shimotsuke-shi, Tochigi (JP)

(72) Inventors: Marina TOBATA, Shimotsuke-shi, Tochigi (JP); Keisuke ARAMAKI, Shimotsuke-shi, Tochigi (JP)

(73) Assignee: DEXERIALS CORPORATION, Shimotsuke-shi, Tochigi (JP)

(21) Appl. No.: 18/277,122

(22) PCT Filed: Jan. 27, 2022
(86) PCT No.: PCT/JP2022/003008

§ 371 Date: Aug. 14, 2023

(30) Foreign Application Priority Data
Feb. 24, 2021 (JP) 2021-027117
Mar. 29, 2021 (JP) 2021-055268

(51) Int. Cl. C09K 5/14; C08J 3/20; C08J 5/18; C08K 3/22; C08K 7/06; H05K 7/20

(52) U.S. Cl. CPC C09K 5/14; C08J 3/203; C08J 5/18; C08K 3/22; C08K 7/06; H05K 7/2039; B29K 2105/12; C08J 2383/04; C08K 2003/2227; C08K 2201/001

(57) ABSTRACT

A heat-conductive sheet includes a binder resin and a fibrous filler having a major axis and dispersed in the binder resin. The major axis of the fibrous filler is arranged at an angle of 70 to 90 degrees with respect to a surface direction of the heat-conductive sheet when viewed in a cross-section along a thickness direction of the heat-conductive sheet. If the heat-conductive sheet is processed to a shape having a thickness of 2 mm and a diameter of 29 mm, and subject to a compression such that the thickness is decreased by 40% of the thickness before the compression, at room temperature for 24 hours, a difference of an angle of the major axis of the fibrous filler after release of the compression and an angle of the major axis of the fibrous filler before the compression is in a range within 10 degrees.

### TECHNICAL FIELD

The present art relates to a heat-conductive sheet and a heat-conductive sheet production method. The present application claims priority based on Japanese Patent Application No. 2021-027117 filed in Japan on Feb. 24, 2021 and Japanese Patent Application No. 2021-055268 filed in Japan on Mar. 29, 2021, and these applications are incorporated in the present application by reference.

### BACKGROUND ART

Conventionally, semiconductor elements installed in various electrical equipment such as personal computers and other equipment generate heat when driven, and if the generated heat accumulates, it may adversely affect driving of the semiconductor element and peripheral equipment, so various cooling methods are used.

Known methods for cooling equipment having a semiconductor element include attaching a fan to the equipment to cool the air inside the equipment housing, attaching a heat sink such as heat-radiating fins or heat-radiating plates to the semiconductor element, and immersing in a fluorine-based inert liquid. When a heat sink is attached to a semiconductor element for cooling, a heat-conductive sheet is provided between the semiconductor element and the heat sink in order to efficiently dissipate the heat of the semiconductor element.

A sheet that disperses and contains a filler (for example, a heat-conductive filler such as carbon fiber) in a binder resin is widely used (see, for example, Patent Literature 1) as an example of a heat-conductive sheet.

Incidentally, as the speed and performance of electronic components such as CPUs (central processing units) in personal computers increase, the amount of heat dissipation tends to increase year by year. However, the chip size of processors and the like has become smaller than or equal to the conventional size due to advances in fine silicon circuit technology, resulting in higher heat flow velocity per unit area. In order to avoid defects and the like due to temperature rise of such electronic components, it is required to dissipate heat and cool electronic components more efficiently.

To improve the heat dissipation properties of a heat-conductive sheet, for example, it is required to lower the heat resistance, which is a measure of the difficulty of heat transfer. To lower the heat resistance of a heat-conductive sheet, it is effective, for example, to improve the adhesiveness of the heat-conductive sheet to a heat-generating body (for example, an electronic component) or a heat-dissipating body (for example, a heat sink).

However, the surface of a heat-conductive sheet sliced from a heat-conductive molded body to form a heat-conductive sheet is usually uneven and therefore tends to have poor adhesion. If the surface of the heat-conductive sheet has poor adhesion, the adhesion of the heat-conductive sheet to the heat-generating body or heat-dissipating body becomes poor during the mounting process, leading to a tendency for difficulty in sufficiently lowering the heat resistance of the heat-conductive sheet. In particular, when the compressive stress of the heat-conductive sheet is low, once the heat-conductive sheet is compressed (crushed), its resilience is small, and therefore when a gap between the heat-generating body and the heat-dissipating body opens, the heat-conductive sheet arranged between the heat-generating body and the heat-dissipating body tends to have difficulty following the gap.

Methods are known to press the surface of a heat-conductive sheet made by slicing a heat-conductive molded body or to leave a heat-conductive sheet made by slicing a heat-conductive molded body standing still for a long time to make the binder component exude onto the surface of the heat-conductive sheet to improve the adhesion between the heat-conductive sheet and the adherend (see, for example, Patent Literatures 2 and 3).

However, when the surface of the heat-conductive sheet is pressed, the binder component may not exude uniformly onto the surface of the heat-conductive sheet, and there is a risk of variations in adhesion depending on the location of the surface of the heat-conductive sheet. Moreover, pressing the surface of the heat-conductive sheet has the same tendency as the case where the heat-conductive sheet is left to stand still for a long time. Moreover, conventional arts have not examined whether the restoring force of the heat-conductive sheet, especially the restoring force of the fibrous filler, is favorable when the heat-conductive sheet is compressed and released.

### CITATION LIST

### Patent Literature

Patent Literature 1: JP 2012-23335
Patent Literature 2: JP 2015-029076
Patent Literature 3: JP 2015-029075

### SUMMARY OF INVENTION

### Problem to be Solved by the Invention

The present art is proposed in view of such conventional conditions, and provides a heat-conductive sheet with favorable restoring force when compression and release are performed on the heat-conductive sheet.

### Means for Solving the Problem

The inventors, through examination, have discovered that when the heat-conductive sheet—in which a fibrous filler is dispersed in a binder resin and the fibrous filler is arranged at an angle of 70 to 90 degrees in the thickness direction when viewed in cross-section—is compressed and released, deterioration of heat resistance can be suppressed due to a restoring force of the fibrous filler being favorable after compression and release.

The present art is a heat-conductive sheet in which a fibrous filler is dispersed in a binder resin and the fibrous filler is arranged at an angle of 70 to 90 degrees in the thickness direction when viewed in cross-section, and when the heat-conductive sheet is compressed and released under condition 1 below, has an arrangement angle of the fibrous filler after release in a range within 10 degrees with respect to the angle before compression when viewed in cross-section.

Condition 1: The thickness of the heat-conductive sheet is compressed 40% from its initial thickness at room temperature for 24 hours and then released.

The heat-conductive sheet production method according to the present art has steps of: preparing a heat-conductive composition including a binder resin and a fibrous filler; forming a molded block from the heat-conductive composition; and slicing the molded block into a sheet shape to obtain a heat-conductive sheet, wherein the heat-conductive sheet is the heat-conductive sheet described above.

### Effect of Invention

According to the present art, it is possible to provide a heat-conductive sheet with favorable restoring force when compression and release are performed on the heat-conductive sheet.

### BRIEF DESCRIPTION OF DRAWINGS

FIG. 1 is a cross-sectional diagram illustrating an example of a heat-conductive sheet.

FIG. 2 is a perspective diagram for describing an example of a method for measuring an arrangement angle of a fibrous filler in the heat-conductive sheet.

FIG. 3 is a perspective diagram for describing an example of a method for measuring the arrangement angle of the fibrous filler in the heat-conductive sheet.

FIG. 4 is a cross-sectional diagram illustrating an example of a heat-conductive sheet before and after compression.

FIG. 5 is a cross-sectional diagram illustrating an example of a semiconductor device to which the heat-conductive sheet is applied.

FIG. 6 is a digital microscope photograph of a cross-section of the heat-conductive sheet before compression.

FIG. 7 is a digital microscope photograph of a cross-section of the heat-conductive sheet after compression and release.

### EMBODIMENTS OF THE INVENTION

In the heat-conductive sheet according to the present art, a fibrous filler is dispersed in a binder resin, and the fibrous filler is arranged at an angle of 70 to 90 degrees in the thickness direction when viewed in cross-section. Moreover, when the heat-conductive sheet according to the present art is compressed and released under condition 1 below, the arrangement angle of the fibrous filler after compression and release is in a range within 10 degrees with respect to the angle before compression when viewed in cross-section.

Condition 1: The thickness of the heat-conductive sheet is compressed 40% from its initial thickness at room temperature for 24 hours and then released.

In this manner, the heat-conductive sheet according to the present art has favorable restoring force, particularly restoring force of the fibrous filler, when compressed and released as in condition 1. That is, the heat-conductive sheet according to the present art returns significantly even if it is crushed significantly as in condition 1. Here, restoring force of the fibrous filler refers to the degree of displacement of the arrangement angle of the fibrous filler in a cross-sectional view of the heat-conductive sheet before and after compression and release, when the heat-conductive sheet is compressed and released under condition 1 described above. The restoring force of the fibrous filler being favorable means that the arrangement angle of the fibrous filler after compression and release when the heat-conductive sheet is compressed and released under condition 1 is in a range within 10 degrees with respect to the angle before compression when viewed in cross-section of the heat-conductive sheet. When the heat-conductive sheet according to the present art is arranged between a heat-generating body (for example, an IC (Integrated Circuit)) and a heat-dissipating body (for example, a heat sink), even if a gap opens between the heat-generating body and the heat-dissipating body, the fibrous filler in the heat-conductive sheet can easily and quickly follow the gap. This suppresses deterioration of the heat resistance of the heat-conductive sheet.

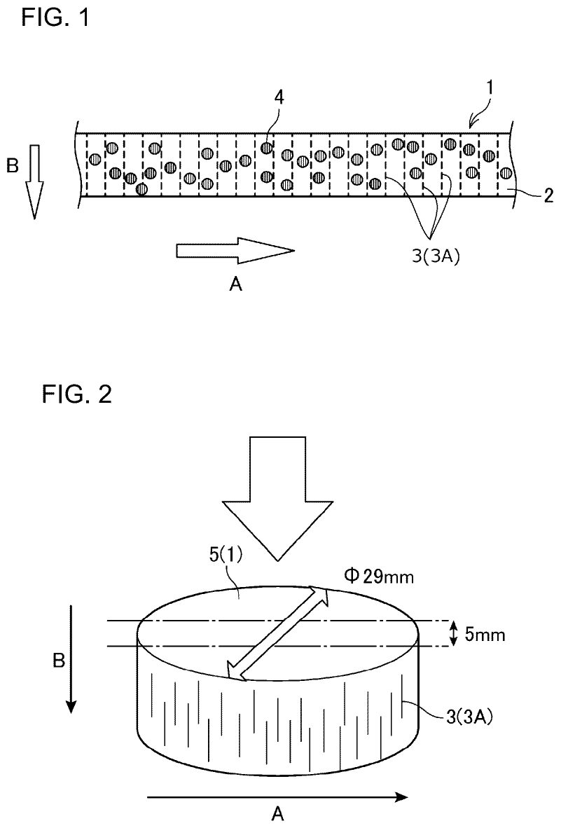

FIG. 1 is a cross-sectional diagram illustrating an example of a heat-conductive sheet. A heat-conductive sheet 1 includes a binder resin 2 and a fibrous filler 3, wherein the fibrous filler 3 is arranged at an angle of 70 to 90 degrees in a thickness direction B when viewed in cross-section. In other words, in the heat-conductive sheet 1, a long axis of the fibrous filler 3 is arranged in a range of 70 to 90 degrees to a surface direction A of the heat-conductive sheet 1. Moreover, the heat-conductive sheet 1 may further include another heat-conductive material 4 other than the fibrous filler 3.

Further, when the heat-conductive sheet 1 is compressed and released under condition 1 described above, the arrangement angle of the fibrous filler 3 after compression and release is in a range within 10 degrees with respect to the angle before compression when viewed in cross-section. That is, the heat-conductive sheet 1 has an angle difference of the fibrous filler 3 of 10 degrees or less before and after compression and release, and the angle of the fibrous filler 3 after compression and release tends to return to the angle (position) before compression.

For the details of condition 1 above, for example, a heat-conductive sheet 1 (sample) of 2 mm thickness and 29 mm diameter is compressed by 40% from an initial thickness (relative to an initial thickness) at room temperature for 24 hours, and the alignment angle of the fibrous filler 3 in the heat-conductive sheet 1 is measured 3 minutes after compression is released. Condition 1 conforms with JIS K6262 in that the size of the heat-conductive sheet 1 is a diameter of 29 mm and the temperature is room temperature. Moreover, in JIS K6262, the time is selective, and “24 hours” in condition 1 is one of the times specified in that standard. With respect to compression according to condition 1, in more detail, first the thickness of the heat-conductive sheet 1 is measured and the heat-conductive sheet 1 is processed to a 29 mm diameter. The processed heat-conductive sheet 1 (sample) is interposed in a jig having SUS304 as the surface, then compressed by 40% with respect to the thickness of the sample. During compression, a spacer having 60% the thickness of the sample thickness is interposed in a screw portion and the screw is tightened. After the screw is tightened, it is confirmed that the spacer has not moved in order to check whether the sample was compressed to a predetermined thickness. Note that in the case of a sample having a sticky surface, it may be interposed in a film to which the sticky material (sample) does not adhere, then compressed. “Room temperature” means a range of 15 to 25° C. as specified in JIS K 0050:2019 (General Rules for Chemical Analysis).

In the heat-conductive sheet, if the angle difference of the fibrous filler 3 before and after compression and release exceeds 10 degrees, when the heat-conductive sheet is arranged between the heat-generating body and the heat-dissipating body, it becomes difficult to make the heat-conductive sheet follow the gap when a gap opens between the heat-generating body and the heat-dissipating body, and as a result, the heat resistance of the heat-conductive sheet tends to easily deteriorate. For the heat-conductive sheet 1, the smaller the angle difference of the fibrous filler 3 before and after compression and release, the more preferable, and the angle may be within 8 degrees, within 7 degrees, within 6 degrees, within 5.6 degrees, within 5.2 degrees, within 4 degrees, within 3.8 degrees, and a range of 3.8 to 5.6 degrees.

The fibrous filler 3 before the heat-conductive sheet 1 is compressed under condition 1 described above may be arranged at an angle of 70 to 90 degrees to the thickness direction B of the heat-conductive sheet 1 when viewed in a cross-section of the heat-conductive sheet 1, may be a range of 80 to 84 degrees, and may be a range of 81.9 to 83.1 degrees. Moreover, the fibrous filler 3 after the heat-conductive sheet 1 is compressed and released under condition 1 described above is also preferably arranged at an angle of 70 to 90 degrees in the thickness direction B of the heat-conductive sheet 1 when viewed in a cross-section of the heat-conductive sheet 1, and for example, may be a range of 70 to 80 degrees, and may be a range of 77.0 to 77.9 degrees.

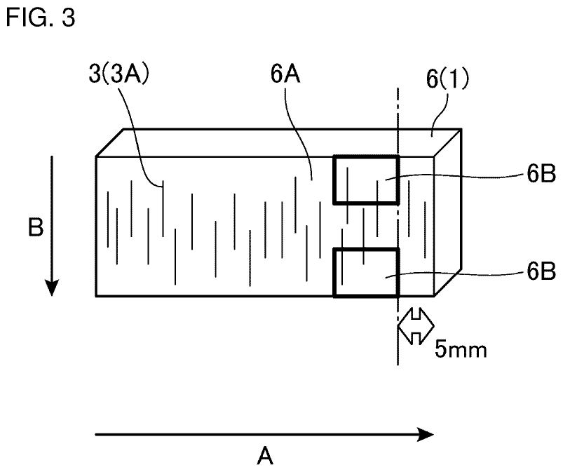

The heat-conductive sheet 1 need not have all the fibrous filler 3 arranged at an angle of 70 to 90 degrees in the thickness direction B when viewed in cross-section. FIG. 2 and FIG. 3 are perspective diagrams for describing an example of a method for measuring the arrangement angle of the fibrous filler 3 in the heat-conductive sheet 1. In FIGS. 2 and 3, the arrow A represents the surface direction of the sample (heat-conductive sheet 1) and the arrow B represents the thickness direction of the sample (heat-conductive sheet 1). For example, as shown in FIG. 2, a sample 5 of a 2 mm thickness and a 29 mm diameter is prepared from the heat-conductive sheet 1, a center portion of the sample 5 in plan view (top surface) is cut to a predetermined width in the thickness direction B, and as shown in FIG. 3, on a cut surface 6A of a cut sample 6, in a range 6B of 5 mm inward and an upper and lower ⅓ from an outer circumference, an average of five measurements of the angle of any fibrous filler 3 may be in the range of 70 to 90 degrees.

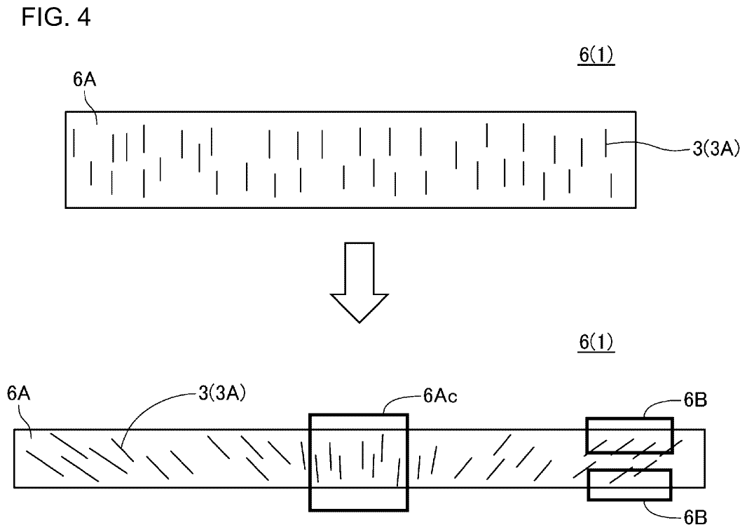

FIG. 4 is a cross-sectional diagram illustrating an example of the heat-conductive sheet before and after compression. The arrow in FIG. 4 means that the heat-conductive sheet 1 (cut sample 6) is compressed under condition 1. That is, the top side of the arrow in FIG. 4 is an example of the heat-conductive sheet 1 (cut sample 6) before compression under condition 1, and the bottom side of the arrow in FIG. 4 is an example of the heat-conductive sheet 1 (cut sample 6) after compression under condition 1. In the range 6B in the cut surface 6A, when compared to other ranges (for example a central portion 6Ac of the cut surface 6A of the cut sample 6), for example, there is a tendency that it is difficult for the fibrous filler 3 in the heat-conductive sheet 1 after compression to become dense in the thickness direction B and that a change of the angle of the fibrous filler 3 before and after compression and release manifests easily. Moreover, in the range 6B in the cut surface 6A, when compared to other ranges (for example a central portion 6Ac of the cut surface 6A), for example, due to a tendency that the heat-conductive sheet 1 more easily tilts when a force is applied when compressed under condition 1 described above, it is considered that there is a tendency for a change of the angle of the fibrous filler 3 before and after compression and release to more clearly manifest easily.

Moreover, the heat-conductive sheet 1 according to the present art has favorable restoring force when compressed and released as in condition 1, and in addition to reducing the angle difference of the fibrous filler 3 before and after compression and release, a change in the external size of the heat-conductive sheet 1 before and after compression and release can also be reduced.

For example, the heat-conductive sheet 1 of a 2 mm thickness and a 29 mm diameter—that is, the sample 5—is compressed by 40% at room temperature for 24 hours and released, and a diameter of the sample 5 after 3 minutes can be made to be 32.0 mm or less, 31.0 mm or less, 30.0 mm or less, 29.9 mm or less, 29.6 mm or less, 29.5 mm or less, and a range of 29.5 to 29.9 mm.

When the heat-conductive sheet 1 is arranged between the heat-generating body and the heat-dissipating body in this manner, even if a gap opens between the heat-generating body and the heat-dissipating body, the external size of the heat-conductive sheet 1 and the fibrous filler 3 in the heat-conductive sheet 1 can be made to follow the gap. Therefore, deterioration of the heat resistance of the heat-conductive sheet 1 can be more effectively suppressed. Moreover, because change of the external size of the heat-conductive sheet 1 before and after compression and release can be reduced, the heat-conductive sheet 1 can be processed according to the shape of the heat-generating body (for example, IC) to more efficiently cool the entire surface of the heat-generating body.

The heat-conductive sheet 1 is preferably relatively soft, for example, a hardness of 25 to 40 on Shore type OO is preferable. By having the hardness of the heat-conductive sheet 1 being a range such as this, the restoring force of the fibrous filler 3 in the heat-conductive sheet 1 and of the external size of the heat-conductive sheet 1 after compression and release is made more favorable. Moreover, a following property to the adherend of the heat-conductive sheet 1 is made more favorable. A hardness of the heat-conductive sheet 1 can be measured by a method of an example described below.

Here, a rubber sheet is used as a heat-conductive sheet having a restoring property. However, rubber sheets generally have a high hardness (harder) on Shore type OO, for example, a load is high for an IC as a heat-generating body or a heat sink as a heat-dissipating body. Moreover, grease (in liquid form) is also used as a heat-conductor that is softer than rubber sheets. However, grease has low shape-following properties to an IC and low returning properties. Here, in a low compression-rate region (compression of less than 40% relative to the initial thickness), even a relatively hard heat-conductive sheet can be crushed, and it is possible to return the angle of the fibrous filler and the external size of the heat-conductive sheet after the heat-conductive sheet is crushed. However, with a hard heat-conductive sheet, when attempting to compress the heat-conductive sheet by 40% relative to the initial thickness as in condition 1, there is a tendency for fractures (for example, cracks or the like enter the heat-conductive sheet) to occur, and for it to be difficult to return the angle of the fibrous filler and the external size of the heat-conductive sheet. Moreover, with a hard heat-conductive sheet, a great deal of force is required to pressurize (compress) the heat-conductive sheet. On the other hand, the heat-conductive sheet 1 according to the present art can adjust its hardness on Shore type OO to 25 to 40, and being softer than a rubber sheet, having better returning properties and shape following property to the adherend than a grease (liquid) sheet. That is, the heat-conductive sheet 1 is soft at a hardness of 25 to 40 on Shore type OO, but has favorable returning properties, and even when compressed under condition 1, the angle of the fibrous filler 3 and the external size of the heat-conductive sheet 1 easily returns.

The thickness of the heat-conductive sheet 1 is not particularly limited and can be appropriately selected according to purpose. For example, the thickness of the heat-conductive sheet 1 can be 0.05 mm or more, or 0.1 mm or more. Moreover, the upper limit of the thickness of the heat-conductive sheet 1 may be 5 mm or less, 4 mm or less, or 3 mm or less. From the perspective of handleability, the heat-conductive sheet 1 preferably has a thickness of 0.1 to 4 mm. The thickness of the heat-conductive sheet 1 can be obtained, for example, from the arithmetic mean of the thickness of the heat-conductive sheet 1 measured at any five locations.

Below, a specific example of constituent elements of the heat-conductive sheet 1 will be described. The heat-conductive sheet 1, for example, includes a binder resin 2, a fibrous filler 3, and another heat-conductive material 4.

### Binder Resin

The binder resin 2 is used to hold the fibrous filler 3 and the other heat-conductive material 4 within the heat-conductive sheet 1. The binder resin 2 is selected according to the mechanical strength, heat resisting property, electrical properties, and other characteristics required for the heat-conductive sheet 1. The binder resin 2 can be selected from thermoplastic resins, thermoplastic elastomers, and thermosetting resins.

Thermoplastic resins include ethylene-alpha olefin copolymers such as polyethylene, polypropylene, and ethylene-propylene copolymers, polymethylpentene, polyvinyl chloride, polyvinylidene chloride, polyvinyl acetate, ethylene-vinyl acetate copolymers, polyvinyl alcohol, polyvinyl acetal, fluorine-based polymers such as polyvinylidene fluoride and polytetrafluoroethylene, polyethylene terephthalate, polybutylene terephthalate, polyethylene naphthalate, polystyrene, polyacrylonitrile, styrene-acrylonitrile copolymers, acrylonitrile-butadiene-styrene copolymer (ABS) resins, polyphenylene-ether copolymer (PPE) resins, modified PPE resins, aliphatic polyamides, aromatic polyamides, polyimides, polyamideimides, polymethacrylic acids, polymethacrylate such as polymethacrylic acid methyl esters, polyacrylic acids, polycarbonates, polyphenylene sulfide, polysulfone, polyethersulfone, polyethernitrile, polyetherketone, polyketone, liquid crystal polymer, silicone resin, ionomer, and the like.

Thermoplastic elastomers include styrene-butadiene block copolymers or their hydrogenated products, styrene-isoprene block copolymers or their hydrogenated products, styrenic thermoplastic elastomers, olefinic thermoplastic elastomers, vinyl chloride thermoplastic elastomers, polyester thermoplastic elastomers, polyurethane thermoplastic elastomers, and polyamide thermoplastic elastomers, and the like.

Thermosetting resins include cross-linked rubbers, epoxy resins, phenolic resins, polyimide resins, unsaturated polyester resins, and diallyl phthalate resins, and the like. Specific examples of cross-linked rubbers include natural rubber, acrylic rubber, butadiene rubber, isoprene rubber, styrene-butadiene copolymer rubber, nitrile rubber, hydrogenated nitrile rubber, chloroprene rubber, ethylene-propylene copolymer rubber, chlorinated polyethylene rubber, chlorosulfonated polyethylene rubber, butyl rubber, halogenated butyl rubber, fluoro rubber, urethane rubber, and silicone rubber.

As the binder resin 2, for example, silicone resin is preferred considering the adhesiveness between the heat-generating surface of the electronic component and the heat sink surface. As the silicone resin, for example, a two-component addition-reaction silicone resin can be used, made of a principal agent containing silicone having alkenyl groups as a main component and a curing catalyst, and a curing agent having hydrosilyl groups (Si—H groups). As a silicone having an alkenyl group, for example, polyorganosiloxane having a vinyl group can be used. The curing catalyst is a catalyst to promote the addition reaction between the alkenyl group in the silicone having an alkenyl group and the hydrosilyl group in the curing agent having a hydrosilyl group. As a curing catalyst, a well-known catalyst can be given as a catalyst used in a hydrosilylation reaction, and, for example, a platinum group curing catalysts, such as platinum group metals simple substances such as platinum, rhodium, and palladium, or platinum chloride can be used. As a curing agent having a hydrosilyl group, for example, polyorganosiloxane having a hydrosilyl group can be used. The binder resin 2 may be used in one type alone or two or more types may be used together.

The content of the binder resin 2 in the heat-conductive sheet 1 is not particularly limited and can be appropriately selected according to purpose. For example, the content of the binder resin 2 in the thermal conductive sheet 1, from the perspective of flexibility and restoring property of the heat-conductive sheet 1, may be 20% by volume or more, 25% by volume or more, 30% by volume or more, or 33% by volume or more. Moreover, the content of the binder resin 2 in the heat-conductive sheet 1, from the perspective of heat conductivity and restoring property of the heat-conductive sheet 1, may be 70% by volume or less, 60% by volume or less, 50% by volume or less, 41% by volume or less, or 39% by volume or less. Moreover, the content of the binder resin 2 in the heat-conductive sheet 1, for example, from the perspective of restoring property of the heat-conductive sheet 1, is preferably 20 to 50% by volume, more preferably more than 35% by volume and 41% by volume or less, and further preferably 39 to 41% by volume.

### Fibrous Filler

The heat-conductive sheet 1 includes the fibrous filler 3. The fibrous filler 3 has a major axis and a minor axis and includes those of a shape having different major axis length and minor axis length, and an aspect ratio (average major axis length/average minor axis length) exceeding 1. The fibrous filler 3 may be used in one type alone or two or more types may be used together. The fibrous filler 3 can be appropriately selected according to purpose, and for example, metallic fibers, carbon fibers, or the like can be used, with carbon fibers being preferred.

For carbon fibers, for example, pitch-based carbon fibers, PAN-based carbon fibers, carbon fibers having graphitized PBO fibers, or carbon fibers synthesized by an arc discharge method, laser evaporation method, CVD (chemical vapor deposition) method, CCVD (catalytic chemical vapor deposition) method, or the like can be used. Among these, from the perspective of heat conductivity, pitch-based carbon fiber is preferable.

The average fiber length (average major axis length) of the fibrous filler 3 can be, for example, 50 to 250 μm, and may be 75 to 220 μm. Moreover, the average fiber diameter (average minor axis length) of the fibrous filler 3 can be appropriately selected according to purpose, and for example, can be 4 to 20 μm, and may be 5 to 14 μm. The aspect ratio of the fibrous filler 3 can be appropriately selected according to purpose, and for example, from the perspective of heat conductivity, for example, can be 8 or higher, and may be 9 to 30. The average major axis length and average minor axis length of the fibrous filler 3, for example, can be measured with a microscope or scanning electron microscope (SEM).

The surface of carbon fibers may be coated using an insulating film according to purpose. In this manner, insulation-coated carbon fibers can be used as the carbon fibers. Insulation-coated carbon fiber has carbon fibers and an insulating film on at least part of the surface of the carbon fiber, and, as required, may contain other components.

The insulating film is made of an electrically insulating material, and is formed by, for example, silicon oxide or a cured material of polymerizable material. Polymerizable materials are, for example, radical polymerizable materials, including organic compounds having polymerizability, resins having polymerizability, and the like. Radical polymerizable materials can be appropriately selected according to purpose, as long as the material uses energy for radical polymerization, such as, for example, a compound having a radical polymerizable double bond. Examples of radical polymerizable double bonds include vinyl groups, acryloyl groups, and methacryloyl groups. A number of radical polymerizable double bonds in a compound having a radical polymerizable double bond, from the perspective of strength including heat resisting property and solvent resistance, is preferably two or more. Compounds having two or more radical polymerizable double bonds include, for example, divinylbenzene (Divinylbenzene: DVB) and compounds having two or more (meth)acryloyl groups. The radical polymerizable material may be used in one type alone or two or more types may be used together. The molecular weight of the radical polymerizable material can be appropriately selected according to the purpose, and for example, can be in a range of 50 to 500. When an insulating film is formed by a cured material of a polymerizable material, the content of constituent units derived from the polymerizable material in the insulating film can be, for example, 50 mass % or more, and can also be 90 mass % or more.

The average thickness of the insulating film can be appropriately selected according to purpose, and from the perspective of achieving high insulation, can be 50 nm or more, and may 100 nm or more, or 200 nm or more. The upper limit of the average thickness of the insulating film can be, for example, 1000 nm or less, and may be 500 nm or less. The average thickness of the insulating film can be determined, for example, by transmission electron microscopy (TEM) observation.

Methods of coating carbon fibers using an insulating film include, for example, a sol-gel method, a liquid phase deposition method, a polysiloxane method, and a method of forming an insulating film made of a cured material of polymerizable material on at least part of the surface of the carbon fiber taught in JP 2018-98515 A.

The content of the fibrous filler 3 in the heat-conductive sheet 1, from the perspective of heat conductivity of the heat-conductive sheet 1, can be, for example, 5% by volume or more, 10% by volume or more, 14% by volume or more, 20% by volume or more, or 25% by volume or more. Moreover, the content of the fibrous filler 3 in the heat-conductive sheet 1, from the perspective of formability of the heat-conductive sheet 1, can be, for example, 30% by volume or less, 28% by volume or less, 25% by volume or less, 23% by volume or less. The content of the fibrous filler 3 in the heat-conductive sheet 1 can be, for example, 5 to 50% by volume, and is preferably 14 to 25% by volume. When two or more types of the fibrous filler 3 are used together, the total amount preferably satisfies the content described above.

### Other Heat-Conductive Materials

The other heat-conductive material 4 is a heat-conductive material other than the fibrous filler 3 described above, such as, for example, an inorganic filler. A shape of the other heat-conductive material 4 can be, for example, spherical, crushed, ellipsoidal, lumpy, granular, or flat. The shape of the other heat-conductive material 4, from the perspective of fillability, is preferably crushed, spherical, ellipsoidal, or the like, and from the perspective of restoring property of the heat-conductive sheet 1, particularly obtaining a more preferable restoring force of the fibrous filler 3 after release when compression and release are performed on the heat-conductive sheet 1, is preferably crushed. Note that crushed means, for example, having a major axis and a minor axis, and the ratio of the lengths of the major axis direction and minor axis direction is 10 or less. The other heat-conductive material 4 may be used in one type alone or two or more types may be used together.

For the other heat-conductive material 4, for example, an inorganic filler, and specifically aluminum oxide (alumina, sapphire), aluminum nitride, aluminum hydroxide, aluminum, zinc oxide, and the like can be used. In particular, from the perspective of restoring property and heat conductivity of the heat-conductive sheet 1, it is preferable to use at least one type of aluminum hydroxide and alumina, and specific examples include situations using alumina alone and situations using aluminum hydroxide alone.

The average particle diameter (D50) of alumina particles can be, for example, 0.1 to 10 μm, and may be 0.1 to 8 μm, 0.1 to 7 μm, or 0.1 to 2 μm. The average particle diameter (D50) of aluminum hydroxide particles can be, for example, 0.1 to 10 μm, and may be 0.1 to 8 μm, 0.1 to 7 μm, or 0.1 to 2 μm.

The average particle diameter of the other heat-conductive material 4 is the particle diameter when the cumulative curve of particle diameter values is calculated from the small particle diameter side of the particle diameter distribution when the overall particle diameter distribution of the other heat-conductive material 4 is 100%, and the cumulative value is 50%. Particle size distribution (particle size distribution) is determined by a volume basis. Particle size distribution measurement methods include, for example, methods using a laser diffraction particle size distribution analyzer.

The other heat-conductive material 4 may be surface treated. Surface treatment includes, for example, treating the other heat-conductive material 4 using a coupling agent such as an alkoxysilane compound. The treatment amount of the coupling agent, for example, can be in a range of 0.1 to 1.5% by volume of the total amount of the other heat-conductive material 4.

Alkoxysilane compounds are compounds having a structure in which one to three of the four bonds of a silicon atom (Si) are bonded to an alkoxy group and the remaining bonds are bonded to an organic substituent. Alkoxy groups having an alkoxysilane compound include, for example, methoxy groups, ethoxy groups, butoxy groups, and the like. Specific examples of alkoxysilane compounds include trimethoxysilane compounds, triethoxysilane compounds, and the like.

The content of the other heat-conductive material 4 in the heat-conductive sheet 1 is not particularly limited and can be appropriately selected according to purpose. When the heat-conductive sheet 1 includes the other heat-conductive material 4, the content of the heat-conductive material 4, from the perspective of restoring property and heat conductivity of the heat-conductive sheet 1, can be more than 21% by volume, may be 36% by volume or more, 40% by volume or more, or 42% by volume or more. Moreover, the content of the other heat-conductive material 4 in thermal conductive sheet 1, from the perspective of restoring property of the heat-conductive sheet 1, can be 50% by volume or less, may be 45% by volume or less, or 40% by volume or less. The content of the other heat-conductive material 4 in the heat-conductive sheet 1, from the perspective of making a more favorable restoring property of the heat-conductive sheet 1, for example, is preferably 36 to 45% by volume. When two or more types of the other heat-conductive material 4 are used together, the total amount preferably satisfies the content described above.

When the heat-conductive sheet 1 contains the fibrous filler 3 and the other heat-conductive material 4, the total content of the fibrous filler 3 and the other heat-conductive material 4 in the heat-conductive sheet 1, from the perspective of restoring property and heat conductivity of the heat-conductive sheet 1 can be 50% by volume or more, may be 55% by volume or more, 59% by volume or more, or 60% by volume or more. Moreover, the total content of the fibrous filler 3 and the other heat-conductive material 4 in the thermal conductive sheet 1, from the perspective of restoring property of the heat-conductive sheet 1, can be less than 77% by volume, may be 67% by volume or less, 65% by volume or less, or 64% by volume or less, 63% by volume or less, 62% by volume or less, or 61% by volume or less. The total of content of the fibrous filler 3 and the other heat-conductive material 4 in the heat-conductive sheet 1 is preferably, for example, 59% by volume or more and less than 65% by volume.

The heat-conductive sheet 1 may further contain other components other than those mentioned above to the extent that the effects of the present art are not impaired. Other components include, for example, dispersants, curing accelerators, retardants, adhesive agents, plasticizers, flame retardants, antioxidants, stabilizers, and colorants.

### Heat-Conductive Sheet Production Method

The heat-conductive sheet production method according to the present art has steps of: preparing a heat-conductive composition including the binder resin 2 and the fibrous filler 3 (also referred to as step A below); forming a molded block from the heat-conductive composition (also referred to as step B below); and slicing the molded block into a sheet shape to obtain the heat-conductive sheet 1 (also referred to as step C below).

The heat-conductive sheet 1 obtained in step C, as described above, has the fibrous filler 3 dispersed in the binder resin 2, and the fibrous filler 3 arranged at an angle of 70 to 90 degrees in the thickness direction B when viewed in cross-section. Further, when the heat-conductive sheet 1 is compressed and released under condition 1 described above, the arrangement angle of the fibrous filler 3 after compression and release is in a range within 10 degrees with respect to the angle before compression when viewed in cross-section.

The heat-conductive sheet 1 obtained using the present production method has favorable restoring force, particularly restoring force of the fibrous filler 3, when compressed and released as in condition 1. Therefore, when the heat-conductive sheet 1 is arranged between the heat-generating body and the heat-dissipating body, even if a gap opens between the heat-generating body and the heat-dissipating body, the fibrous filler 3 in the heat-conductive sheet 1 can be made to easily and quickly follow the gap. This suppresses deterioration of the heat resistance of the heat-conductive sheet 1.

### Step A

In step A, a heat-conductive composition containing the binder resin 2 and the fibrous filler 3 is prepared. The heat-conductive composition may include the other heat-conductive material 4 described above. The heat-conductive composition may be uniformly mixed by known methods together with various additives and volatile solvents.

### Step B

In step B, a molded block is formed from the heat-conductive composition. Molding methods of the molded block include extrusion molding, die casting, and the like. Extrusion molding and die casting methods are not particularly limited, and can be appropriately applied from among various known extrusion molding and die casting methods, according to viscosity of the heat-conductive composition and characteristics and the like required by the heat-conductive sheet 1. For example, in an extrusion molding method, when the heat-conductive composition is extruded from the die, or in a die cast method, when the heat-conductive composition is pressed into the die, the binder resin 2 flows and the major axis of the fibrous filler 3 is oriented along the flow direction.

The size and shape of the molded block can be determined according to the size of the heat-conductive sheet required. Examples include a rectangular body with a cross section of 0.5 to 15 cm in vertical size and 0.5 to 15 cm in horizontal size. The length of the rectangular body may be determined as needed. In extrusion molding, it is easy to form a columnar shaped molded block, made of a cured material of the heat-conductive composition, with the major axis of the fibrous filler 3 oriented in the extrusion direction.

It is preferable that the obtained molded block is thermoset. The curing temperature in thermosetting can be appropriately selected according to purpose, and for example, when the binder resin 2 is a silicone resin, can be in the range of 60° C. to 120° C. The curing time in thermosetting, for example, can be in a range of 30 minutes to 10 hours.

### Step C

In step C, the molded block is sliced into a sheet shape to obtain the heat-conductive sheet 1 with the major axis of the fibrous filler 3 oriented in the thickness direction B. The surface of the sheet obtained by slicing (sliced surface) has the fibrous filler 3 exposed. The slicing method is not particularly limited and can be appropriately selected from among known slicing devices depending on the size and mechanical strength of the molded block. Slicing devices include, for example, an ultrasonic cutter, a plane, or the like. As the slicing direction of the molded block, when the molding method is an extrusion molding method, because there is a case where the major axis of the fibrous filler 3 is oriented in the extrusion direction, it is preferably 60 to 120 degrees relative to the extrusion direction, more preferably a direction of 70 to 100 degrees, and further preferably a direction of 90 degrees (orthogonal).

In this manner, in the production method having step A, step B, and step C, a heat-conductive sheet 1 in which the fibrous filler 3 is dispersed in the binder resin 2, wherein the fibrous filler 3 is arranged at an angle of 70 to 90 degrees in the thickness direction B when viewed in cross-section, and which, when compressed and released under condition 1 described above, has an arrangement angle of the fibrous filler 3 after compression and release in a range within 10 degrees with respect to the angle before compression when viewed in cross-section, can be obtained.

The production method of the heat-conductive sheet 1 is not limited to the example described above, and may, for example, have a further step D in which the sliced surface is pressed after step C. In a production method having a step D in this manner a surface of the heat-conductive sheet 1 obtained in step C is further smoothened and adhesion to another member can further improve. As a method of pressing, a pair of pressing devices made of a flat board and a press head having a flat surface. Moreover, the surface of the heat-conductive sheet 1 may be pressed by a pinch roll.

A pressure when pressing, for example, can be a range of 0.1 to 100 MPa, may be a range of 0.1 to 1 MPa, or a range of 0.1 to 0.5 MPa. A pressing time can be appropriately selected according to the pressure when pressing, a sheet area, or the like, and can be, for example, a range of 10 seconds to 5 minutes, or may be in a range of 30 seconds to 3 minutes.

As one embodiment, a press head having a heater built in may be used to press while heating. A press temperature, for example, can be a range of 0 to 180° C., may be a range of room temperature (for example 25° C.) to 100° C., or a range of 30 to 100° C. In order to further increase an effect of pressing and shorten the pressing time, pressing may be performed at a glass transition temperature (Tg) or higher of the binder resin constituting the molding sheet.

### Electronic Equipment

The heat-conductive sheet 1 can be, for example, arranged between the heat-generating body and the heat-dissipating body to make electronic equipment (thermal device) having a structure arranged between them to release the heat generated by the heat-generating body to the heat-dissipating body. The electronic equipment has at least a heat-generating body, a heat-dissipating body, and a heat-conductive sheet 1, and as needed, may further have other members.

Heat-generating bodies are not particularly limited, and include, for example, integrated circuit elements such as CPUs, GPUs (Graphics Processing Units), DRAMs (Dynamic Random Access Memory), and flash memory, transistors, resistors, and other electronic components that generate heat in electric circuits. Moreover, a component that receives a light signal such as a light transceiver in communication equipment is also included in the heat-generating body.

Heat-dissipating bodies are not particularly limited, and include bodies that are used in combination with integrated circuit elements, transistors, optical transceiver housings, and the like, such as heat sinks and heat spreaders. Materials of the heat sinks and the heat spreaders include, for example, copper and aluminum. Heat-dissipating bodies other than heat spreaders and heat sinks may be anything that conducts and dissipates to the outside heat generated from a heat source, and, for example, radiators, coolers, die pads, printed circuit boards, cooling fans, Peltier elements, heat pipes, vapor chambers, metal covers, and housings are mentioned. A heat pipe has, for example, a cylindrical, substantially cylindrical or flattened tubular hollow structure.

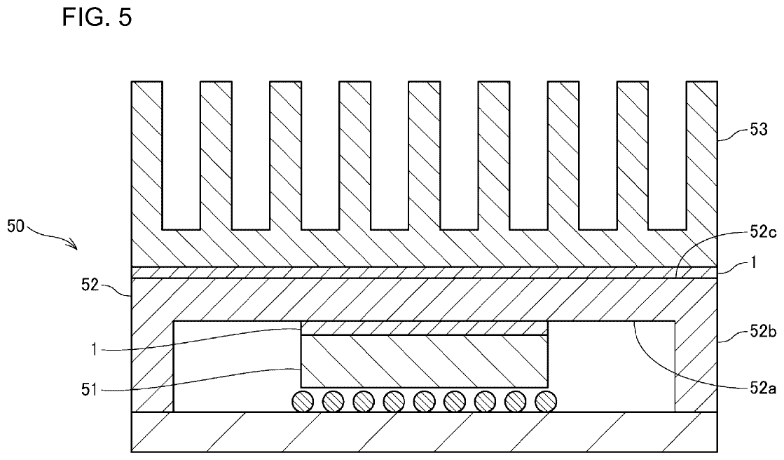

FIG. 5 is a cross-sectional diagram illustrating an example of a semiconductor device to which the heat-conductive sheet is applied. For example, the heat-conductive sheet 1, as shown in FIG. 5, is mounted on a semiconductor device 50 built into various electronic equipment and interposed between the heat-generating body and the heat-dissipating body. The semiconductor device 50 shown in FIG. 5 is provided with an electronic component 51, a heat spreader 52, and the heat-conductive sheet 1, wherein the heat-conductive sheet 1 is interposed between the heat spreader 52 and the electronic component 51. The heat-conductive sheet 1, by being interposed between the heat spreader 52 and a heat sink 53, together with the heat spreader 52, constitutes a heat-dissipating member that dissipates heat of the electronic component 51. A mounting location of the heat-conductive sheet 1 is not limited to between the heat spreader 52 and the electronic component 51 or between the heat spreader 52 and the heat sink 53, and can be appropriately selected according to the configuration of the electronic equipment or semiconductor device. The heat spreader 52 is, for example, formed as a square plate, and has a main surface 52a facing the electronic component 51 and a side wall 52b erected along the periphery of the main surface 52a. The heat spreader 52 is provided with the heat-conductive sheet 1 on the main surface 52a surrounded by the sidewall 52b, and is provided with the heat sink 53 via the heat-conductive sheet 1 on an other surface 52c opposite the main surface 52a.

### EXAMPLES

Examples of the present art will be described below. The present art is not limited to these examples.

### Example 1

In Example 1, as shown in Table 1, a silicone composition was prepared by mixing 45% by volume of 2 μm average particle diameter alumina particles coupling-processed using silane coupling agent and 14% by volume of 200 μm average fiber length pitch-based carbon fiber as a fibrous filler in a two-liquid addition-reaction type liquid silicone resin. Note that a substance having polyorganosiloxane as a main component at 41% by volume was used for the two-liquid addition-reaction type liquid silicone resin and it was prepared so that a hardness of the sheet after completion on Shore type OO was 25. The obtained silicone composition was extrusion molded into a hollow square cylinder die (50 mm×50 mm) to form a 50 mm square silicone molded body. The silicone molded body was heated in an oven at 100° C. for 6 hours to make the silicone cured material. The silicone cured material was cut using a slicer to a thickness of 2.0 mm to obtain a heat-conductive sheet.

### Example 2

In Example 2, as shown in Table 1, a heat-conductive sheet was obtained in the same manner as Example 1 except in that instead of 45% by volume of 2 μm average particle diameter alumina particles coupling-processed using silane coupling agent, 45% by volume of 1.2 μm average particle diameter crushed aluminum hydroxide particles coupling-processed using silane coupling agent was used, and that it was prepared so that a hardness of the sheet after completion on Shore type OO was 30.

### Example 3

In Example 3, as shown in Table 1, a heat-conductive sheet was obtained in the same manner as Example 1 except in that a silicone composition was prepared by mixing 36% by volume of 4 μm average particle diameter alumina particles coupling-processed using silane coupling agent and 25% by volume of 120 μm average fiber length pitch-based carbon fiber as a fibrous filler in a two-liquid addition-reaction type liquid silicone resin, and in that as the two-liquid addition-reaction type liquid silicone resin, a substance having polyorganosiloxane as a main component was used at 39% by volume and it was prepared so that a hardness of the sheet after completion on Shore type OO was 40.

### Comparative Example 1

In Comparative Example 1, as shown in Table 1, a heat-conductive sheet was obtained in the same manner as Example 1 except in that a silicone composition was prepared by mixing 42% by volume of 4 μm average particle diameter alumina particles coupling-processed using silane coupling agent and 23% by volume of 150 μm average fiber length pitch-based carbon fiber as a fibrous filler in a two-liquid addition-reaction type liquid silicone resin, and in that as the two-liquid addition-reaction type liquid silicone resin, a substance having polyorganosiloxane as a main component was used at 35% by volume and it was prepared so that a hardness of the sheet after completion on Shore type OO was 40.

### Comparative Example 2

In Comparative Example 2, as shown in Table 1, a heat-conductive sheet was obtained in the same manner as Example 1 except in that a silicone composition was prepared by mixing 21% by volume of 4 μm average particle diameter alumina particles coupling-processed using silane coupling agent, 24% by volume of 1.3 μm average particle diameter aluminum nitride particles, and 22% by volume of 150 μm average fiber length pitch-based carbon fiber as a fibrous filler in a two-liquid addition-reaction type liquid silicone resin, and in that as the two-liquid addition-reaction type liquid silicone resin, a substance having polyorganosiloxane as a main component was used at 33% by volume and it was prepared so that a hardness of the sheet after completion on Shore type OO was 50.

### Comparative Example 3

In Comparative Example 3, as shown in Table 1, a heat-conductive sheet was obtained in the same manner as Example 1 except in that a silicone composition was prepared by mixing 36% by volume of 4 μm average particle diameter alumina particles coupling-processed using silane coupling agent, 25% by volume of 1.3 μm average particle diameter aluminum nitride particles, and 16% by volume of 15 μm average particle diameter aluminum powder in a two-liquid addition-reaction type liquid silicone resin, and in that as the two-liquid addition-reaction type liquid silicone resin, a substance having polyorganosiloxane as a main component was used at 23% by volume and it was prepared so that a hardness of the sheet after completion on Shore type OO was 40. In this manner, in comparative example 3, a heat-conductive sheet without carbon fiber was obtained.

### Bulk Thermal Conductivity

For bulk thermal conductivity, heat resistance was measured for each heat-conductive sheet by a method compliant with ASTM-D5470, the thickness (mm) of the heat-conductive sheet at the time of measurement was plotted on the horizontal axis, the heat resistance (° C.·cm²/W) of the heat-conductive sheet was plotted on the vertical axis, and the bulk thermal conductivity (W/m·K) of the heat-conductive sheet was calculated from the slope of the plot. For the heat resistance of the heat-conductive sheet, three types of thermal conductive sheets having different thicknesses were prepared and the heat-conductive sheets of each thickness were measured. The results are shown in Table 1.

### Preparation of Samples for Evaluation

The heat-conductive sheets obtained in the examples and comparative examples were processed to a 29 mm diameter to prepare samples for evaluation. Three or more samples were prepared for (1) external size confirmation, (2) cross-sectional observation before compression, and (3) cross-sectional observation after compression and release.

### Exterior Size of Samples after Compression and Release

The external size of the samples after compression and release was determined by visually measuring the maximum and minimum lengths using calipers and taking the average value. Specifically, a sample of 2 mm thickness and 29 mm diameter was compressed by 40% with respect to its initial thickness at room temperature for 24 hours, and the external size of the sample was measured 3 minutes after release of the compression. The results are shown in Table 1.

### Carbon Fiber Inclination Before Compression

For cross-sectional observation of sample 5 (heat-conductive sheet 1) before compression, as illustrated in FIG. 2, a center portion of sample 5 was cut using a razor blade to a 5 mm width in the thickness direction B to obtain sample 6. Further, as illustrated in FIG. 3, in sample 6, an angle of any carbon fiber 3A was measured at 5 points in a range 6B of 5 mm inward and an upper and lower ⅓ from an outer circumference of the cross-section, and the average value was obtained. Measurement of the angle of the carbon fiber 3A was performed using a microscope VHX-5000 (Keyence Corporation) at a magnification of 100×. The angles of five points of the carbon fiber 3A were measured so that the angle of the carbon fiber 3A would be from 0 to 90 degrees after the parallel of sample 6 was produced.

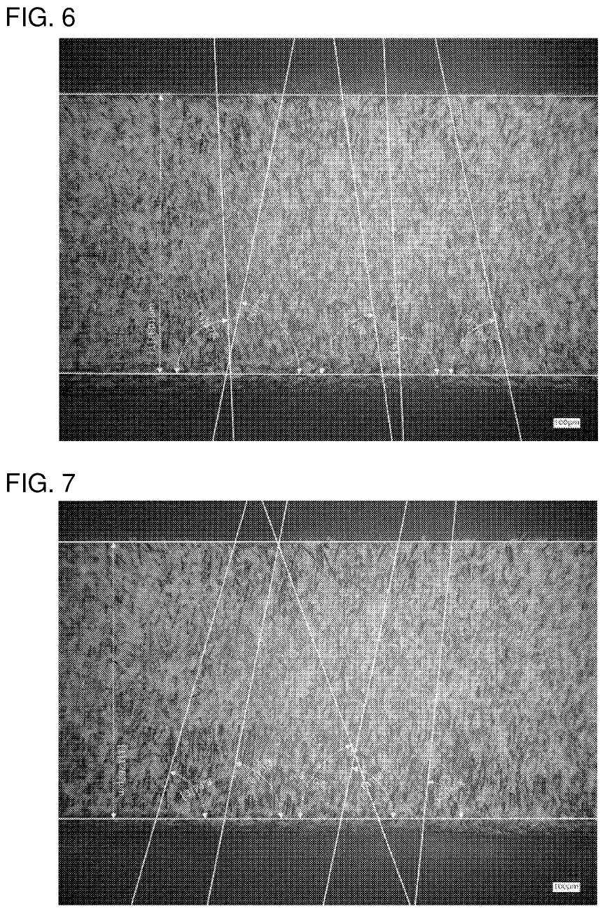

FIG. 6 is a digital microscope photograph of a cross-section of the heat-conductive sheet before compression. As an example, a calculation method of an angle of the carbon fiber in sample 6 of Example 3 will be described. As in “[6] 93 degrees” illustrated in FIG. 6, where the angle exceeds 90 degrees, the angle was determined as 180 degrees−93 degrees=87 degrees. The angles of five points of the carbon fiber 3A in sample 6 of example 3 before compression were 87 degrees, 79 degrees, 82 degrees, 93 degrees (87 degrees), and 78 degrees, with an average of 82.6 degrees. The results are shown in Table 1.

### Carbon Fiber Inclination after Compression and Release

Cross-sectional observation of sample 6 after compression and release was performed at the same time as cross-sectional observation of sample 6 before compression. Sample 5 illustrated in FIG. 2 was compressed by 40% with respect to its initial thickness at room temperature for 24 hours, and 3 minutes after release of the compression, as illustrated in FIGS. 2 and 3, a center portion of sample 5 after compression and release was cut using a razor blade to a 5 mm width in the thickness direction B to obtain sample 6. On a cut surface (surface) of sample 6, an angle of any carbon fiber 3A was measured at 5 points in a range 6B of 5 mm inward and an upper and lower ⅓ from an outer circumference of the cross-section, and the average value was obtained.

FIG. 7 is a digital microscope photograph of a cross-section of the heat-conductive sheet after compression and release. As an example, a calculation method of an angle of the carbon fiber 3A in sample 6 of Example 3 will be described. As illustrated in FIG. 7, the angles of five points of the carbon fiber 3A in sample 6 of Example 3 after release of the compression were 74 degrees, 79 degrees, 70 degrees, 78 degrees, and 84 degrees, with an average of 77.0 degrees. The results are shown in Table 1.

### Carbon Fiber Angle Difference Before and After Compression and Release

The difference (in degrees) of the average of the angles of the five points of carbon fiber 3A in sample 6 before and after compression and release was found. The results are shown in Table 1.

### Hardness on Shore Type 00

The hardness of the heat-conductive sheet on Shore type OO was measured in accordance with ASTM-D2240 by layering five 2 mm thickness heat-conductive sheets to make a 10 mm thickness, and measuring five points on one side for a total of ten points on both sides, and taking the average value of the measurement results. The results are shown in Table 1.

TABLE 1

| | | | | Comparative | Comparative | Comparative |
|---|---|---|---|---|---|---|
| | Example 1 | Example 2 | Example 3 | Example 1 | Example 2 | Example 3 |
| Silicone resin | 41 | 41 | 39 | 35 | 33 | 23 |
| [% by volume] | | | | | | |
| Aluminum hydroxide | 0 | 45 | 0 | 0 | 0 | 0 |
| [% by volume] | | | | | | |
| Alumina | 45 | 0 | 36 | 42 | 21 | 36 |
| [% by volume] | | | | | | |
| Aluminum nitride | 0 | 0 | 0 | 0 | 24 | 25 |
| [% by volume] | | | | | | |
| Aluminum | 0 | 0 | 0 | 0 | 0 | 16 |
| [% by volume] | | | | | | |
| Carbon fiber | 14 | 14 | 25 | 23 | 22 | 0 |
| [% by volume] | | | | | | |
| Total filler amount | 59 | 59 | 61 | 65 | 67 | 77 |
| [% by volume] | | | | | | |
| Bulk thermal | 20 | 18 | 30 | 30 | 35 | 5 |
| conductivity | | | | | | |
| External size after a 2 | 29.5 | 29.6 | 29.9 | 32.4 | 33.1 | 33.4 |
| mm × ϕ 29 mm sheet is | | | | | | |
| compressed by 40% and | | | | | | |
| released [mm] | | | | | | |
| Inclination of carbon | 81.9 | 83.1 | 82.6 | 82.1 | 81.9 | — |
| fiber before | | | | | | |
| compression | | | | | | |
| [degrees] | | | | | | |
| Inclination of carbon | 78.1 | 77.9 | 77.0 | 69.2 | 62.6 | — |
| fiber after compression | | | | | | |
| and release [degrees] | | | | | | |
| Angle difference of | 3.8 | 5.2 | 5.6 | 12.9 | 19.3 | — |
| carbon fiber before and | | | | | | |
| after compression and | | | | | | |
| release [degrees] | | | | | | |
| Type OO | 25 | 30 | 40 | 40 | 50 | 40 |

The heat-conductive sheets obtained in Examples 1 to 3 have the fibrous filler 3 dispersed in the binder resin 2 and the fibrous filler 3 arranged at an angle of 70 to 90 degrees in the thickness direction B when viewed in cross-section, and it was found that when compression and release are performed under condition 1 above, the heat-conductive sheets have an arrangement angle of the fibrous filler 3 after compression and release in a range within 10 degrees with respect to the angle before compression when viewed in cross-section. That is, it was found that the heat-conductive sheets obtained in Examples 1 to 3 have favorable restoring force, particularly restoring force of the carbon fiber 3A (fibrous filler 3), when compression and release are performed as in condition 1. Therefore, when the heat-conductive sheets obtained in Examples 1 to 3 are arranged between the heat-generating body and the heat-dissipating body, even if a gap opens between the heat-generating body and the heat-dissipating body, the fibrous filler 3 in the heat-conductive sheets can be made to easily and quickly follow the gap. This is believed to suppress deterioration of heat resistance of the heat-conductive sheets obtained in Examples 1 to 3.

Moreover, it was found that when the heat-conductive sheets obtained in Examples 1 to 3 were made to a 2 mm thickness and 29 mm diameter, a diameter 3 minutes after compression by 40% at room temperature for 24 hours then release, is 32.0 mm or less. That is, the heat-conductive sheets obtained in Examples 1 to 3 were also found to have a small change in external size after compression and release.

Meanwhile, it was found that when the heat-conductive sheets obtained in Comparative Examples 1 and 2 were compressed and released under condition 1 described above, the arrangement angle of the fibrous filler 3 after compression and release is not in a range within 10 degrees with respect to the angle before compression when viewed in cross-section. That is, it was found that the heat-conductive sheets obtained in Comparative Examples 1 and 2 do not have favorable restoring force, particularly restoring force of the carbon fiber 3A (fibrous filler 3), when compression and release are performed as in condition 1 compared to the heat-conductive sheets of Examples 1 to 3. Moreover, the heat-conductive sheets obtained in Comparative Examples 1 to 3 were found to have a large change in external size after compression and release compared to Examples 1 to 3.

### DESCRIPTION OF REFERENCE SIGNS

1 Heat-conductive sheet, 2 Binder resin, 3 Fibrous filler, 3A Carbon fiber, 4 Other heat-conductive material, 5 Sample, 6 Cut sample, 6A Cut surface, 6Ac Central portion, 50 Semiconductor device, 51 Electronic component, 52 Heat spreader, 52a Main surface, 52b Side wall, 52c Other surface, 53 Heat sink

1. A heat-conductive sheet comprising:
a binder resin; and
a fibrous filler having a major axis, and dispersed in the binder resin,
wherein
the major axis of the fibrous filler is arranged at an angle of 70 to 90 degrees with respect to a surface direction of the heat-conductive sheet when viewed in a cross-section along a thickness direction of the heat-conductive sheet, and
if the heat-conductive sheet is processed to a shape having a thickness of 2 mm and a diameter of 29 mm, and subject to a compression such that the thickness is decreased by 40% of the thickness before the compression, at room temperature for 24 hours, a difference of an angle of the major axis of the fibrous filler after release of the compression and an angle of the major axis of the fibrous filler before the compression is in a range within 10 degrees when viewed in the cross-section.

2. The heat-conductive sheet according to claim 1 wherein if the heat-conductive sheet is processed to a shape having a thickness of 2 mm and a diameter of 29 mm, and subject to a compression such that the thickness is decreased by 40% of the thickness before the compression, at room temperature for 24 hours, the heat-conductive sheet has a diameter of 32.0 mm or less after release of the compression.

3. The heat-conductive sheet according to claim 1, wherein a content of the fibrous filler in the heat-conductive sheet is 5 to 50% by volume relative to a total volume of the heat-conductive sheet.

4. The heat-conductive sheet according to claim 1, wherein a content of the binder resin in the heat-conductive sheet is 20 to 50% by volume relative to a total volume of the heat-conductive sheet.

5. The heat-conductive sheet according to claim 1, wherein a hardness of the heat-conductive sheet on a Shore type OO is 25 to 40.

6. The heat-conductive sheet according to claim 1, wherein the binder resin comprises a silicone resin.

7. The heat-conductive sheet according to claim 1, wherein the fibrous filler comprises a pitch-based carbon fiber.

8. The heat-conductive sheet according to claim 1, further comprising a heat-conductive material other than the fibrous filler, wherein a total content of the fibrous filler and the heat-conductive material in the heat-conductive sheet is less than 65% by volume relative to a total volume of the heat-conductive sheet.

9. The heat-conductive sheet according to claim 1, further comprising a heat-conductive material other than the fibrous filler, wherein the heat-conductive material comprises at least one of aluminum hydroxide and alumina.

10. A heat-conductive sheet production method comprising:
mixing components comprising a binder resin and a fibrous filler to obtain a heat-conductive composition;
molding the heat-conductive composition to form a molded block; and
slicing the molded block into a sheet shape to obtain the heat-conductive sheet according to claim 1.

11. Electronic equipment comprising:
a heat-generating body;
a heat-dissipating body; and
the heat-conductive sheet according to claim 1 disposed between the heat-generating body and the heat-dissipating body.
